(19) United States
(12) Patent Application Publication
(10) Pub. No.: US 2013/0134848 A1
(43) Pub. Date: May 30, 2013

(54) CASING OF MOBILE DEVICE

(71) Applicant: Ping-Hsu CHU, Taipei (TW)

(72) Inventor: Ping-Hsu CHU, Taipei (TW)

(73) Assignee: INVENTEC CORPORATION, Taipei (TW)

(21) Appl. No.: 13/351,410

(22) Filed: Jan. 17, 2012

(30) Foreign Application Priority Data
Nov. 25, 2011 (TW) 100143448

(51) Int. Cl. H05K 5/02

(52) U.S. Cl. 312/265

(57) ABSTRACT

A casing of a mobile device includes a front casing and a back casing. The front casing includes a column and at least two detent hooks. The back casing includes a protruding part and an actuating part. The protruding portion includes at least two fasteners. The actuating part is disposed in the hole and includes at least two cantilevers. The cantilevers are connected to the fasteners respectively. When an external force is applied to the actuating part, the cantilevers push the fasteners to get away from the detent hooks, so that the detent hooks are detached from the snapping parts. Therefore, the front casing and the back casing can be quickly assembled or disassembled.

### CROSS-REFERENCE TO RELATED APPLICATIONS

This non-provisional application claims priority under 35 U.S.C. §119(a) on Patent Application No(s). 100143448 filed in Taiwan, R.O.C. on Nov. 25, 2011, the entire contents of which are hereby incorporated by reference.

### BACKGROUND

1. Technical Field

The present disclosure generally relates to a casing of a mobile device, and more particularly to a casing of a mobile device capable of being disassembled quickly.

2. Related Art

Hardware of a portable electronic device is becoming lighter, smarter, and thinner. Manufacturers need to design a light, smart, and thin product such as a panel computer popular in recent years in a certain available space. Compared with a conventional notebook computer, the panel computer has an advantage that it has functions similar to those of the notebook but has a very small volume. Furthermore, a user can input instructions on a display screen of the panel computer by means of touching the screen, and thus the space for a keyboard is saved. Compared with the conventional notebook computer, the panel computer has advantages of having a small volume and being portable. A user even can easily operate the panel computer by carrying the panel computer in hands. With the above advantages, the panel computer becomes a new favorite in the market. All the manufactures researches and develops the panel computer to meet the strong demand of customers.

In the structure of a conventional panel computer, the upper casing and the lower casing are connected by a plurality of fastening components, for example, metal screws or copper nails. In addition, frames and casings of a panel computer are fixed and connected together by gel substances. Although metal screws or copper nails used as the fastening components have the advantage of high fixity, the metal screw is heavy and expensive resulting in increasing manufacturing cost and weight. Therefore, a light, thin, and low-cost panel computer cannot be achieved. Moreover, when mental screws are used to fix the structure of a panel computer, a large number of works are needed to assemble and disassemble the panel computer with automatic or manual tools. In such a way, the assembly speed is reduced, the cost of human resources is increased, and the disassembling speed is reduced during maintenance. If the gel substance is used to connect the frames and the casings, the disassembling cannot be implemented once the structure is formed. If the disassembling is performed by force, the original structure is easily destroyed. Furthermore, stickiness of the gel substance is decreased with time, and thus the fixity and the integrality of the connected structure are decreased.

### SUMMARY

A casing of a mobile device disclosed in the present disclosure comprises a front casing and a back casing. The front casing comprises a column and at least two detent hooks. The column extends outwards from a first surface of the front casing. The at least two detent hooks are disposed on a circumference surface of the column. The back casing is connected to the front casing in a detachable manner. The back casing comprises a protruding part and an actuating part. The protruding part protrudes from a second surface of the back casing, forms a hole penetrating the back casing, and comprises at least two fasteners disposed on ends of the hole respectively. The fasteners are connected and fixed to the detent hooks in a detachable manner, and the first surface faces the second surface. The actuating part is disposed in the hole and comprises at least two cantilevers. The cantilevers are connected to the fasteners respectively. When an external force is applied to the actuating part, the at least two cantilevers push the at least two fasteners to get away from the detent hooks, so that the detent hooks are detached from the fasteners.

Features and practice the present disclosure are described in detail below with reference to embodiments and the accompanying drawings.

### BRIEF DESCRIPTION OF THE DRAWINGS

The present disclosure will become more fully understood from the detailed description given herein below for illustration only, and thus are not limitative of the present disclosure, and wherein:

FIG. 1 is a schematic diagram showing the structure of a casing of a mobile device according to the first embodiment of the present disclosure;

FIG. 2 is a schematic diagram showing the configuration of a casing of a mobile device according to the first embodiment of the present disclosure;

FIG. 3 is a schematic diagram showing the configuration of a part of the front casing and the back casing according to the first embodiment of the present disclosure;

FIG. 4 is a schematic diagram showing the configuration of a part of the casing of a mobile device according to the first embodiment of the present disclosure;

FIG. 5A is a top view of a part of the back casing according to the first embodiment of the present disclosure;

FIG. 5B is a top view of a part of a back casing according to a second embodiment of the present disclosure;

FIG. 6A is a first section view showing the operation of the casing of a mobile according to the first embodiment of the present disclosure;

FIG. 6B is a second section view showing the operation of the casing of a mobile device according to the first embodiment of the present disclosure;

FIG. 7 is a section view of the casing of a mobile device according to a third embodiment of the present disclosure;

FIG. 8 is a schematic diagram showing configuration of a part of the front casing and the back casing according to a fourth embodiment of the present disclosure; and

FIG. 9 is a top view showing a part of the back casing according to the fourth embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

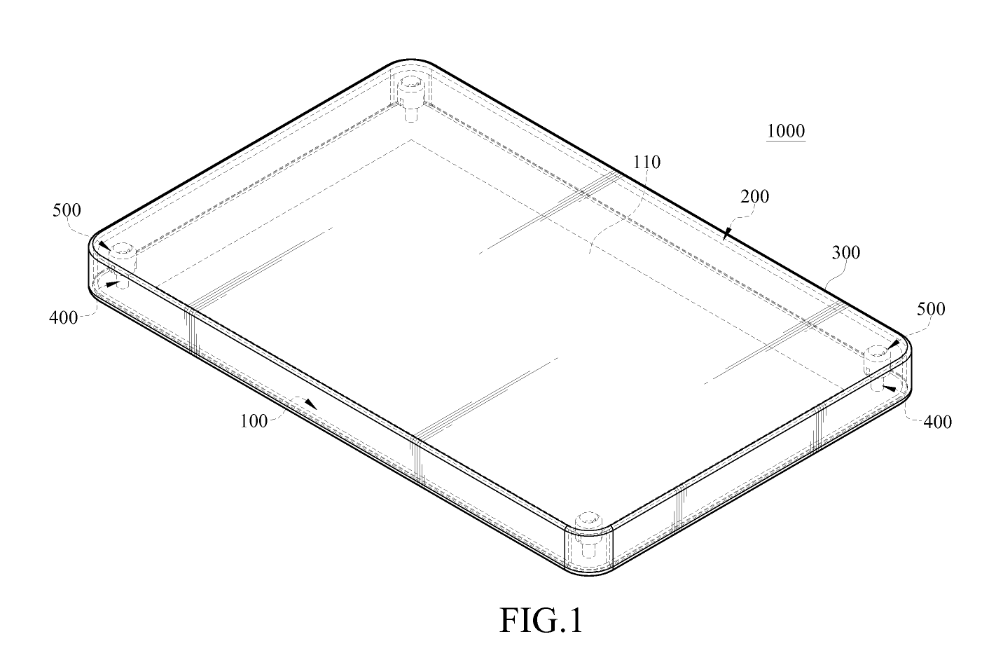

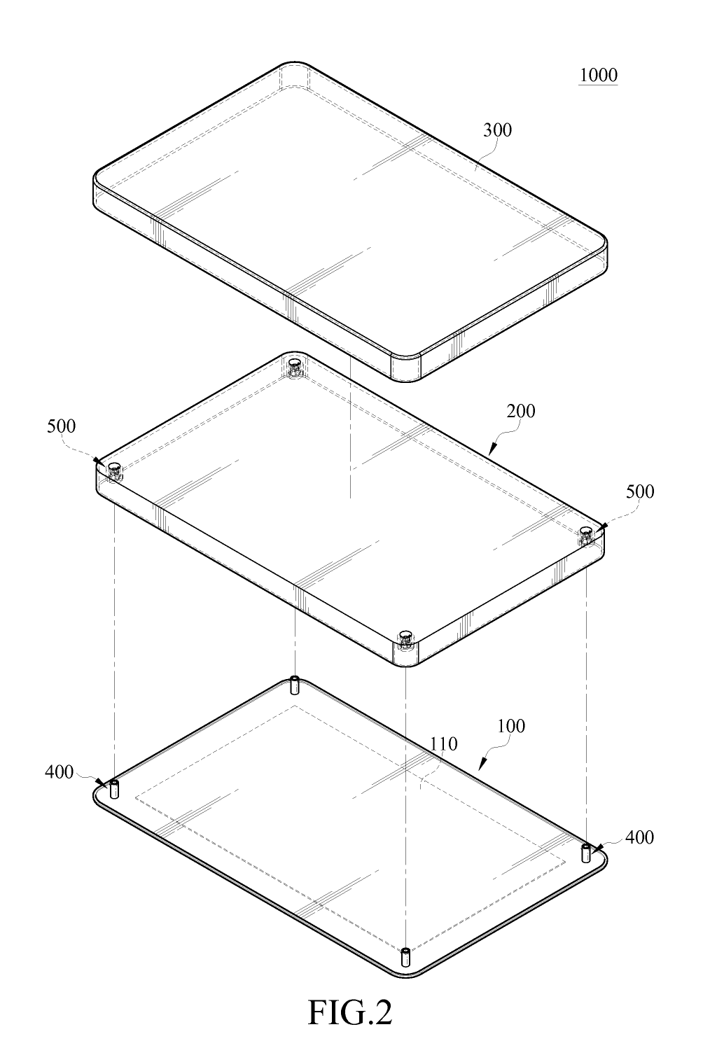

A structure of a casing of a mobile device according to an embodiment of the present disclosure is described in the following. FIG. 1 is a schematic diagram showing the structure of a casing of a mobile device according to the first embodiment of the present disclosure. FIG. 2 is a schematic diagram showing the configuration of a casing of a mobile device according to the first embodiment of the present disclosure. Referring to FIGS. 1 and 2, the casing 1000 of a mobile device comprises a front casing 100, a back casing 200, and a cover 300. The front casing 100 comprises two columns 400 at its two corners. The columns 400 extend outwards from a first surface 120 of the front casing 100. In this and some embodiments, each column 400 is perpendicular to the first surface 120. The back casing 200 comprises two bonding parts 500 corresponding to the columns 400 of the front casing 100. The front casing 100 and the back casing 200 are capable of being connected to or disassembled from each other by the columns 400 and the connecting parts 500. The cover 300 is disposed on the side of the back casing 200 facing the front casing 100 and covers other sides of the back casing 200. The cover 300 is used to protect the back casing 200 to increase the strength of the casing 1000. In addition, the front casing 100 has a display area 110 to expose a display module or a touch module (not shown).

The mobile device disclosed in this embodiment of the present disclosure is a panel computer, which is not intended to limit the present disclosure. In other embodiments, the mobile device is a notebook computer, a hand-held game machine, a portable music device, or a smart phone, which is not intended to limit the present disclosure.

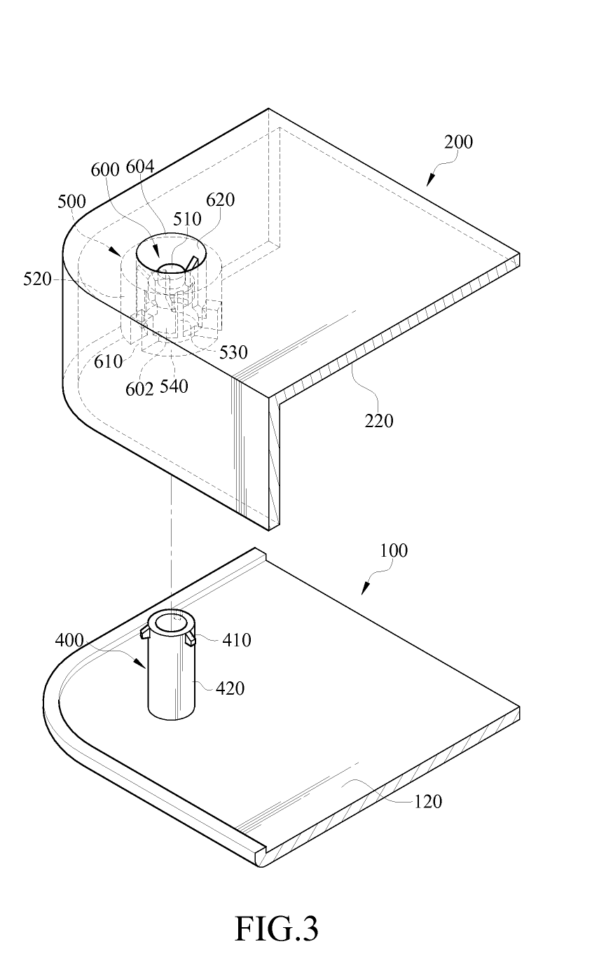

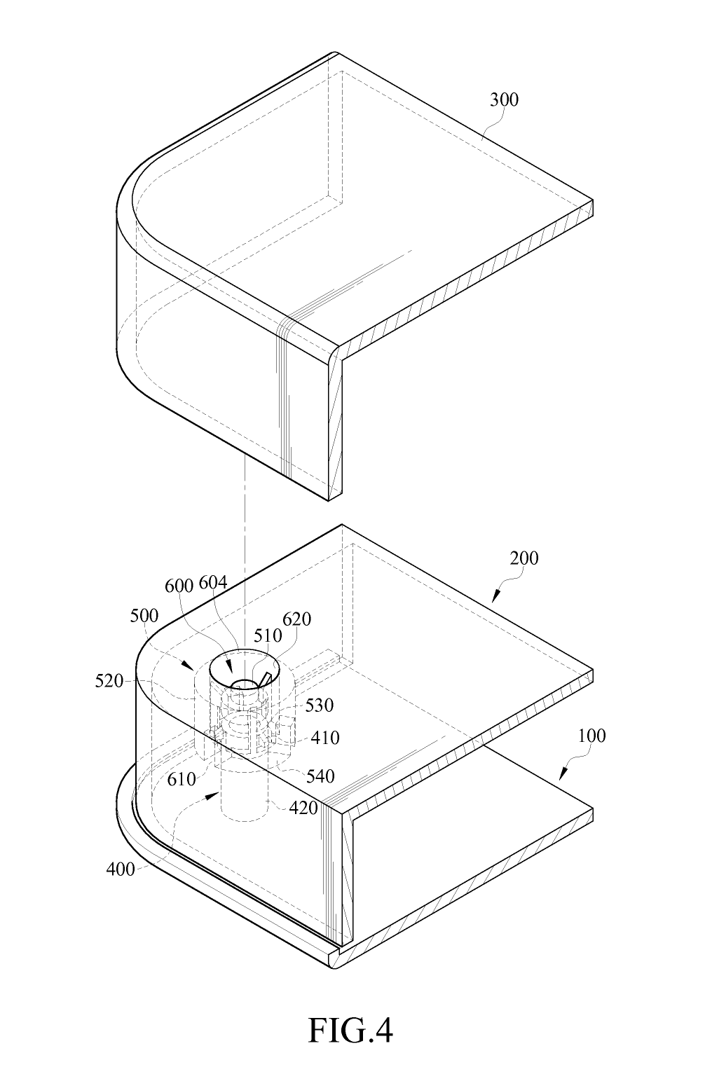

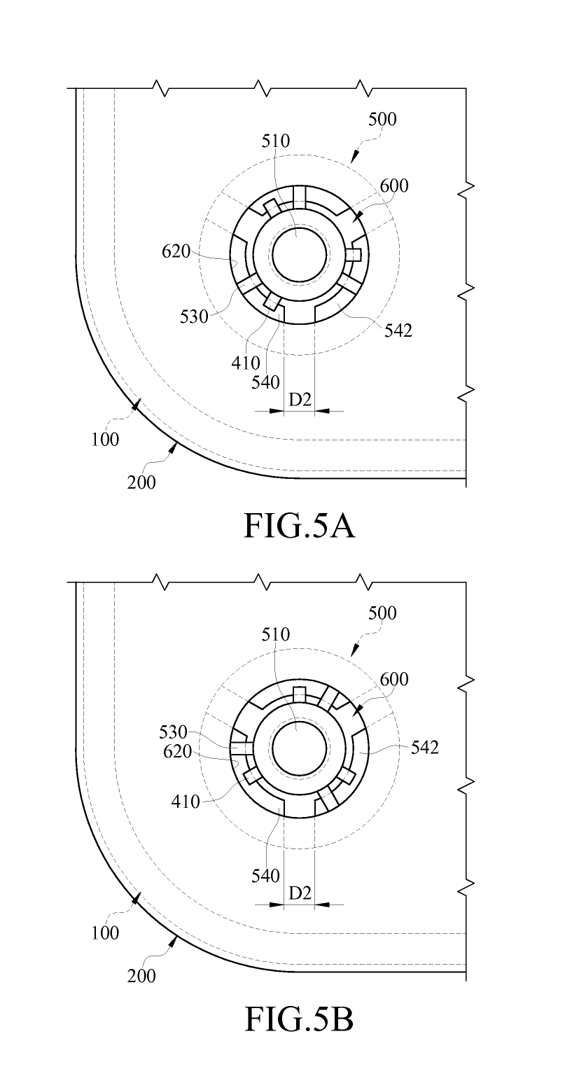

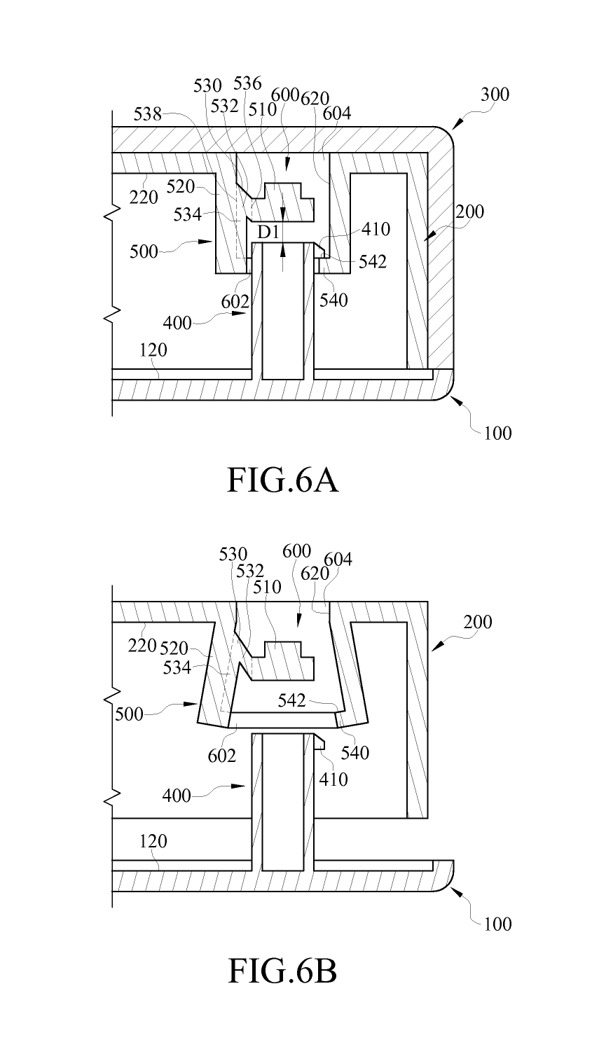

The connection of corners of the front casing, the back casing, and the cover will be described in the following. For details, references may be made to FIGS. 3, 4, 5A, and 6A. FIG. 3 is a schematic diagram showing the configuration of a part of the front casing and the back casing according to the first embodiment of the present disclosure. FIG. 4 is a schematic diagram showing the configuration of a part of the casing of a mobile device according to the first embodiment of the present disclosure. FIG. 5A is a top view of a part of the back casing according to the first embodiment of the present disclosure. FIG. 6A is a first section view showing the operation of the casing of a mobile according to the first embodiment of the present disclosure. The columns 400 of the front casing 100 extend outwards from the first surface 120 of the front casing 100. The circumference surface 420 of the column 400 has three detent hooks 410. An angle between every two detent hooks 410 at the center the column 400 is 120 degrees. The back casing 200 comprises a protruding part 520 and an actuating part 510. The protruding portion 520 protrudes from a second surface 220 of the back casing 200 and extends towards the front casing 100. A hole 600 is formed in the protruding portion 520, and penetrating the back casing 200. The protruding portion 520 comprises three fasteners 540 regularly disposed, each in an opening 602 which formed on the wall forming the hole 600. The fasteners 540 may fasten the detent hooks 410 in a detachable manner respectively. A third surface 542 of a fastener 540 contacts the detent hook 410. The actuating part 510 is disposed in the hole 600. The actuating part 510 comprises three cantilevers 530. The cantilevers 530 are connected to the corresponding fasteners 540 respectively. When an external force is applied to the actuating part 510 to push the cantilever 530, the protruding part 520 makes the fastener 540 gets away from the detent hook 410, so that the detent hook 410 is detached from the fastener 540. The protruding part 520 and the actuating part 510 in the connecting part 500 are of an elastic material. When an external force is applied, the protruding portion 520 and the actuating portion 510 are deformed elastically. When the external force disappears, the protruding part 520 and the actuating part 510 are restored to original shapes without permanent deformation.

In this embodiment, a first distance D1 exists between the actuating part 510 and the column 40. That is, the actuating part 510 does not contact the column 400 when the front casing 100 and the back casing 200 are connected and fastened. In other words, the actuating part 510 enables the detent hook 410 to be detached from the back casing 200 by the pushing of the cantilever 530.

Moreover, a second distance D2 exists in a gap 610 between every two fasteners 540. That is, the fasteners 540 are not connected to one another, and each combination of the cantilever 530, the fastener 540, and the detent hook 410 is separated from the other two combinations. In other words, if only one cantilever 530 is moved under the external force to drive the corresponding fastener 540, only one detent hook 410 is detached from the back casing 200.

Furthermore, each of the cantilevers 530 has a first arm 532 and a second arm 534. A first end 536 of the first arm 532 is connected to the actuating portion 510, and a second end 538 of the first arm 532 extends towards another opening 604 of the hole 600 to connect to one end of the second arm 534. The other end of the second arm 534 is connected to the third surface 542 of the fastener 540. The first arm 532 and the second arm 534 has an angle of inclination towards the opening 604, and thus the actuating part 510 can easily push the first arm 532 and the second arm 534 to drive the fastener 540 to move.

In an embodiment, a side of the second arm 534 is connected to an inner side wall 620 of the hole 600. When an external force is applied to the actuating part 510, the second arm 534 pushes the protruding part 520 and the fastener 540 to move, so that the detent hook 410 is disassembled from the fastener 540. The cantilevers 530 are connected to middle of the third surfaces 542 of the fasteners 540 respectively.

In other embodiments, the second arm 534 is not directly connected to the inner side wall 620 of the hole 600 (not shown in figures), and the second arm 534 is directly connected to the third surface 542 of the fastener 540. Therefore, the external force may be directly applied to the fastener 540 without by the protruding part 520.

Furthermore, as shown in FIG. 4, after the front casing 100 and the back casing 200 are assembled together, the cover 300 can be assembled on the back casing 200.

A casing of a mobile device according to another embodiment of the present disclosure is described in the following. FIG. 5B is a top view of a part of a back casing according to a second embodiment of the present disclosure. Referring to FIG. 5B, in this embodiment, the cantilevers 530 are connected to the third surfaces 542 of the fasteners 540 respectively. Compared with the above embodiment, where the cantilever 530 is located one end of the third surface 542 of the fastener 540, the configuration in this embodiment does not affect the operation process and result of the detent hook 410 being connected to or detached from the fastener 540.

A diagram showing the operation for disassembling a casing of a mobile device according to an embodiment of the present disclosure is described in the following. FIG. 6B is a second section view showing the operation of the casing of a mobile device according to the first embodiment of the present disclosure. In this embodiment, FIG. 6A shows a fixed state of the front casing 100, the back casing 200 and the cover 300 after the connecting. As stated above, the front casing 100 fastens the fastener 540 by the detent hook 410 to be fixed to the back casing 200. As shown in FIG. 6B, the cover 300 is firstly taken off, and then an external force is applied to the opening 604 of the hole 600 to press the actuating part 510. Since the actuating part 510 is connected to each cantilever 530, all cantilevers 530 drive the fasteners 540 and the protruding parts 520 to elastically move outwards so as to expand the opening 602, so that the detent hook 410 is detached from the snapping part 540, changing the original connecting structure. Finally, the front casing 100 is disassembled from the back casing 200, completing the disassembling operation.

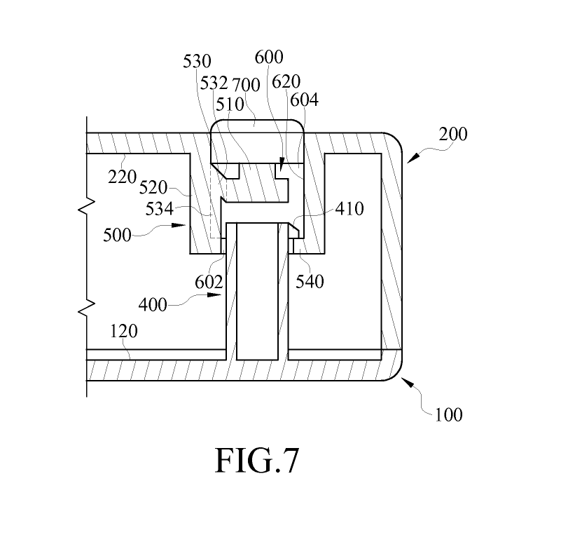

A casing of a mobile device according to still another embodiment of the present disclosure is described in the following. FIG. 7 is a section view of the casing of a mobile device according to a third embodiment of the present disclosure. Referring to FIG. 7, the casing of the embodiment further comprises a pressing part 700 on the actuating part 510. When an external force is applied to the pressing part 700, the pressing part 700 drives the actuating part 510 to move. If the cover 300 is replaced with the back casing 200, the pressing part 700 may be used to mask the actuating part 510, thereby preventing the internal structure from being exposed to the outside resulting in the external substances contacting the internal structure. In this embodiment, a material of the pressing part 700 may be rubber, plastic, or metal, which is not intended to limit the present disclosure.

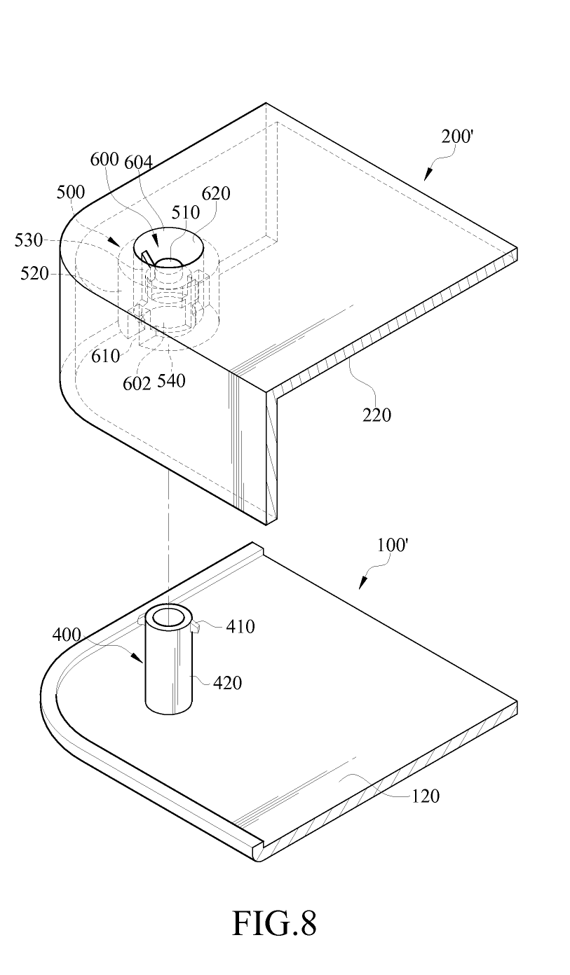

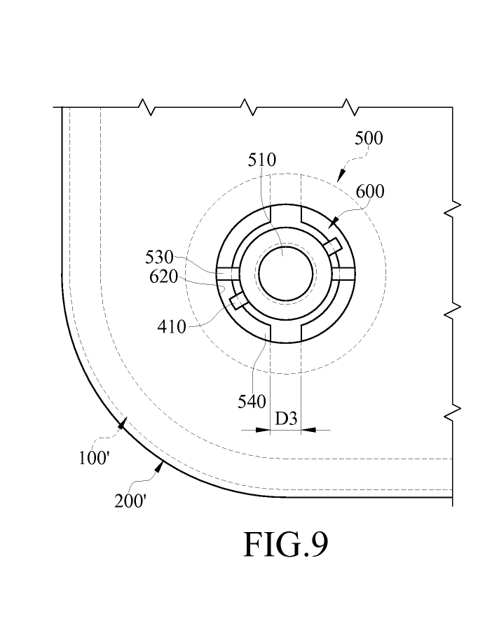

A casing of a mobile device according to still another embodiment of the present disclosure is described in the following. FIG. 8 is a schematic diagram showing configuration of a part of the front casing and the back casing according to a fourth embodiment of the present disclosure. FIG. 9 is a top view showing a part of the back casing according to the fourth embodiment of the present disclosure. Components in FIG. 8 are similar to those in FIG. 3, and components in FIG. 9 are similar to those in FIG. 5A. Therefore, the same reference number represents the same or similar element. In this embodiment, the circumference surface 420 of a column 400 of the front casing 100′ only has two detent hooks 410. An angle between the two detent hooks 410 at the center of the column 400 is 180 degrees. That is, the two detent hooks 410 are symmetrically disposed on the circumference surface 420 of the column 400. A protruding part 520 of the back casing 200′ only comprises two fasteners 540 symmetrically disposed, each in an opening 602 of a hole 600. A actuating part 510 is disposed in the hole 600. The actuating part 510 comprises two cantilevers 530. The cantilevers 530 of the actuating part 510 are connected to the fasteners 540. When an external force is applied to the actuating part 510, the two cantilevers 530 respectively push the fasteners 540 to move out of the protruding part 520, so that the two detent hooks 410 are disassembled from the two fasteners 540. A second distance D2 exists in a gap 610 between the fasteners 540, and the two fasteners 540 are separated from each other. In addition, in the embodiment of the present disclosure, the number of the fasteners 540, the detent hooks 410, and the cantilevers 530 are not intended to limit the present disclosure. In other embodiments, the effect of the present disclosure can be achieved as long as the number is at least two.

In the casing of a mobile device provided by the embodiments of the present disclosure, an actuating part, three cantilevers, and three fasteners are disposed in the hole. The actuating part is formed at the intersection of the three cantilevers. A cantilever is connected to a fastener by the inner side wall of the hole. When an external force presses the actuating part, both the fasteners and the protruding part are moved outwards, so that the detent hook is disassembled from the back casing. In such a way, the front casing and the back casing can be easily disassembled if they are connected by detent hooks instead of screws, copper nails, or gel substances. Therefore, the conventional problems of difficult disassembling, being heavy, a high cost, and a low assembly speed are solved. According to the present disclosure, lightness, easy assembly and disassembling, and a low material cost are achieved.

What is claimed is:

1. A casing of a mobile device, comprising:
a front casing, comprising:
a column, extending outwards from a first surface of the front casing; and
at least two detent hooks, disposed on the circumference surface of the column; and
a back casing, connected to the front casing in a detachable manner, the back casing comprises:
a protruding part protruding from a second surface of the back casing and forming a hole penetrating the back casing, the protruding part comprising at least two fasteners disposed on one end of the hole, wherein the fasteners are bonded and fixed to the detent hooks in a detachable manner, and the first surface faces the second surface; and
a actuating part disposed in the hole, comprising at least two cantilevers, the cantilevers of the actuating part are connected to the fasteners respectively, when an external force is applied to the actuating part, the cantilevers push the fasteners to get away from the detent hooks, so that the detent hooks are detached from the fasteners.

2. The casing of a mobile device according to claim 1, wherein each of the cantilevers has a first arm and a second arm, a first end of the first arm is connected to the actuating part, a second end of the first arm extends to connect one end of the second arm, and the other end of the second arm is connected to one of the fasteners.

3. The casing of a mobile device according to claim 2, wherein when the external force is applied to the actuating part 510 to push the cantilevers 530, the protruding part 52 makes the fasteners 540 to move far away from the detent hooks 410, so that the detent hooks are detached from the fasteners.

4. The casing of a mobile device according to claim 2, wherein the second arms of the cantilevers are connected to a side surface of the fasteners respectively, and the detent hooks are fixed to the side surface of the fasteners respectively in a detachable manner.

5. The casing of a mobile device according to claim 1, wherein a first distance exists between the actuating part and the column.

6. The casing of a mobile device according to claim 1, wherein the back casing further comprises a pressing part disposed on the actuating part, and when another external force is applied to the pressing part, the pressing part drives the actuating part to move.

7. The casing of a mobile device according to claim 1, wherein a second distance exists between the fasteners to separate the fasteners.
